(19) United States
(12) Patent Application Publication
(10) Pub. No.: US 2010/0148282 A1
(43) Pub. Date: Jun. 17, 2010

(54) WAFER JOINING METHOD, WAFER COMPOSITE, AND CHIP

(76) Inventors: Dieter Donis, Stuttgart (DE); Jens Koenig, Markgroeningen (DE)

Correspondence Address: KENYON & KENYON LLP, ONE BROADWAY, NEW YORK, NY, 10004, US

(21) Appl. No.: 12/600,415

(22) PCT Filed: Jul. 4, 2008
(86) PCT No.: PCT/EP08/58652

§ 371 Date: Nov. 16, 2009

(30) Foreign Application Priority Data
Jul. 31, 2007 (DE) 10 2007 035 788.7

(51) Int. Cl. H01L 29/66; H01L 21/50; H01L 23/58

(52) U.S. Cl. 257/414; 438/113; 257/618; 257/E21.499; 257/E23.002; 257/E29.166

(57) ABSTRACT

A method for joining a first wafer to at least a second wafer. The method is characterized by the following operations of depositing a sinterable bonding material on at least one of the wafers, joining the wafers, and sintering the bonding material by heating. Furthermore, a wafer composite and a chip are also described.

### FIELD OF THE INVENTION

The present, invention relates to a method for joining a first wafer with at least a second wafer, a wafer composite, and a chip.

### BACKGROUND INFORMATION

German patent document DE 10 2004 021 258 A1 discusses how to fasten two wafers to each other by soldering. To this end, soldering means are deposited on metallic bonding frames, which respectively surround one electronic circuit. After bringing the wafers to be bonded into contact, the soldering means are melted and a stable soldering connection forms between the wafers. What is disadvantageous in the known wafer bonding method is that very broad bonding frames must be used in order to be able to accommodate the soldering means that are liquefied during the soldering. Depending on the application case, these bonding frames may take up between 10 and 45 percent of the resulting chip surface. Moreover, during the soldering process the temperature load of the electronic components is high, and this may cause damage to the electronic components in the worst case.

### SUMMARY OF THE INVENTION

Thus, the objective that provides the basis of the exemplary embodiments and/or exemplary methods of the present invention is to provide a joining method for wafers, in which only small off-limits zones have to be provided on the wafers and in which the temperature load of the electronic components on the wafers is minimized. Furthermore, the objective consists of providing a correspondingly optimized wafer composite of at least two wafers, and a chip that is separated out from the wafer composite and correspondingly optimized.

With regard to the method, this object is achieved by the features described herein, and with regard to the wafer composite, by the features further described herein, and with regard to the chip, by the features still further described herein. Advantageous further refinements of the exemplary embodiments and/or exemplary methods of the present invention are provided and described herein. The framework of the exemplary embodiments and/or exemplary methods of the present invention also includes all combinations of at least two of the features disclosed in the specification, in the description and/or in the figures, as described herein.

The idea providing the basis of the exemplary embodiments and/or exemplary methods of the present invention is to use a sintering process to join (to bond) at least two wafers, of which, for example, a first wafer may be designed as a sensor wafer having an electronic circuit, and a second wafer may be designed as a cap wafer for encapsulating the electronic circuit of the first wafer. The advantage relative to the known soldering method is that the bonding material used does not liquefy, at least not completely, which means that the off-limits zones, in particular, bonding frames, that have to be provided are fundamentally smaller, and as a result, more, as a percentage, of the surface on a wafer may be used for providing electronic circuits, so that in the further sequence, a larger number of chips may be produced using one wafer.

An additional essential advantage of the method according to the present invention is that the temperature load of the electronic components is significantly lower in the sinter process than in the known soldering process. The sinter temperature may be less than 350°, in particular, less than 300°, and may be less than 250° C. Normally, the actual operating temperature of a chip resulting from the method designed according to the concept of the present invention is significantly higher than this sinter temperature (joining temperature). The method according to the present invention proceeds as follows: Initially, sinterable bonding material, in particular having a particle size distribution in the nanometer and/or micrometer range, is deposited on at least one of the wafers to be bonded. In a next step, the wafers are joined, i.e. placed on each other or beside each other, in particular after they have been aligned with each other, and the sinterable bonding material is heated so that a sinter process results.

In the sense of the exemplary embodiments and/or exemplary methods of the present invention, “join” does not necessarily mean a direct contacting of the wafers. Rather, a sandwich structure having two outer wafers and bonding material disposed between them is obtained. In this context, it is within the framework of the exemplary embodiments and/or exemplary methods of the present invention for the heating of the sinter material to begin even before the joining of the wafers to be bonded. Alternatively, the heating takes place only after the wafers are joined.

Depending on the particle size distribution of the bonding material used, it may be necessary to exert a compression force on the wafers, in addition to the sinter temperature, in particular of less than 350° C., in particular less than 300° C., which may be less than 250° C. in order to obtain a stable sinter connection. In particular, in the event of a particle size distribution in the micrometer range, it may be advantageous to produce a compression force between approximately 15 and 60 MPa, in particular between approximately 25 to 45 MPa. In the event of a particle size distribution in the nanometer range, low pressures of under 2 MPa, in particular of approximately 1 MPa or below, are already sufficient for producing a stable sinter connection. Depending on the particle size distribution, it is even conceivable to omit a separate compression arrangement for producing a compression force, so that the own weight alone of at least one wafer disposed above the first wafer is sufficient to produce a sufficient, minimal compression force.

There are different possibilities for heating the bonding material to sinter temperature. In accordance with a first alternative, the at least two wafers are heated together with the bonding material in an oven process to a temperature at which a sintering of the bonding material takes place. In this context, the sinter temperature (joining temperature) may be below 350° C., in particular, below 300° C., which may be below 250° C. If it is necessary to apply a compression force for sintering, then the compression arrangement may also be disposed inside of the sinter oven.

Additionally, or alternatively, according to a second alternative, it is possible to not heat entirely the wafers to be bonded to each other, but rather to heat the bonding material only locally, in targeted manner. In particular, laser radiation is suitable for this, which may be a laser scanner. The laser beam may radiate through one of the at least two wafers to be bonded, in particular a cap wafer, which is designed at least essentially in a manner that is transparent for the laser radiation. Using a laser scanner allows for complex bonding material contours (sinter contours) to be traced as well. The targeted, local heating of the bonding material has fundamental advantages relative to the oven process.

For one thing, the wafers are heated only in the actual contact region for the bonding material, so that electronic components are protected. Moreover, time is saved, since in contrast to the sinter oven process, relatively protracted heating and cooling are not necessary. The heating duration and/or the laser beam intensity may be adjusted such that the result is sinter temperatures below 350° C., which may be below 300° C., or which may be below 250° C. The laser-supported heating process may be performed only after the wafers to be bonded have been brought into contact.

A further refinement of the method may be used, according to which at least the sinter step occurs in a vacuum, in particular in order to be able to produce hermetically sealed chips. In this process, the process management of the sinter process must be adjusted such that the resulting sinter connection features a closed partial-vacuum-impervious porosity.

In order to implement a maximum stability of the bond connection between the at least two wafers, a specific embodiment is advantageous in which the wafers are metallized before the bonding material is deposited, which may be at least in the subsequent contact region for the bonding material, for example using a nickel/gold compound and/or a chrome/gold compound and/or a chrome/silver compound, etc. The metalizing may take place in the form of bonding frames that surround the actual electronic circuit on at least one of the two wafers.

The bonding material is deposited advantageously (in particular, exclusively) on metallized regions of at least one of the wafers, which may be on at least one bonding frame that surrounds an electronic circuit designed on at least one of the wafers and/or surrounds a micromechanical element, in order to produce subsequently circuits and/or micromechanical elements that are completely surrounded by the bonding material, i.e., chips having a peripheral bond connection.

Particularly good results were achieved using a bonding material that contains silver particles. The particle size distribution of the silver particles may be in the nanometer range and the d₅₀ value of the particle size distribution in a first, preferred bonding material is between approximately 2 nm and 10 nm, and in a second, preferred bonding material is between approximately 30 nm and 50 nm. Moreover, it is possible to use bonding material in which the silver particles feature a particle size distribution in the micrometer range. In this context, good results were achieved using silver particles having a d₅₀ value between approximately 2-30 μm. In principle, the following is valid: The larger the particles, the higher the compression force required to produce a sinter connection.

A specific embodiment is particularly advantageous in which the bonding material includes, in addition to silver particles, which may form the largest proportion of the mass, additives, such as organic material and/or glass solder and/or gold solder, in particular in order to obtain a closed porosity in the sinter connection, in order to subsequently obtain vacuumized chips.

A specific embodiment in which the bonding material is paste-like in order to prevent a spreading to a region of the wafer outside of the bonding frame is preferred. Additionally or alternatively, it is possible for dry powder to be used as the bonding material, in particular.

In particular, it is possible to deposit paste-like bonding material through stencil printing and/or screen printing and/or spraying and/or dispensing. The bonding material may be deposited only on one of two wafers to be connected to each other, whereupon the wafer without bonding material is aligned in particular relative to the wafer situated below, and is brought into contact with it, if necessary by applying a compression force, which may be below 60 MPa.

The method according to the present invention is suitable not only for producing capped electronic circuits and/or micromechanical elements having two wafers. Also, the method according to the present invention may alternatively be used to produce so-called wafer stacks, made up of at least three superposed wafers, it being preferable for at least two of the wafers, or two circuits disposed on different wafers, to be connected to each other in an electrically conductive manner through throughplating.

In particular, after the (at least partial) hardening of the bonding material, the bonded wafers are divided into individual chips or chip stacks. This may be performed using known methods, such as a sawing process, for example. The individual chips may be divided by a laser-supported cutting process or sawing process, which may be in a region outside of the bonding frames.

The exemplary embodiments and/or exemplary methods of the present invention also results in a wafer composite of at least two wafers, a sintered bonding connection, which may be produced according to one of the previously described methods, being provided between the at least two wafers. A specific embodiment of the wafer composite, in which the sintered bonding material features a closed porosity, is particularly preferred.

Furthermore, the exemplary embodiments and/or exemplary methods of the present invention results in a chip that may be produced by dividing an aforementioned wafer composite. The chip designed according to the concept of the present invention is characterized by a sintered bond connection between the at least two wafer planes of the chip. In this context the, in particular closed-pore, bonding connection may surround the actual electronic circuit and/or the micromechanical element, a vacuum atmosphere may be surrounded in a leak-proof manner by the frame-shaped bonding material.

Additional advantages, features and details of the present invention derive from the description of the exemplary embodiments as well as from the figures.

### BRIEF DESCRIPTION OF THE DRAWINGS

FIG. 1 shows a flow chart of the method according to the present invention using a sinter oven process.

FIG. 2 shows an alternative sequence of the method using laser radiation to heat locally the bonding material.

FIG. 3 shows a section of one of at least two wafers to be connected to each other.

FIG. 4 shows an alternative sequence of the bonding method for producing wafer stacks.

### DETAILED DESCRIPTION

Identical components and components having the same function are labeled by the same reference symbols in the figures.

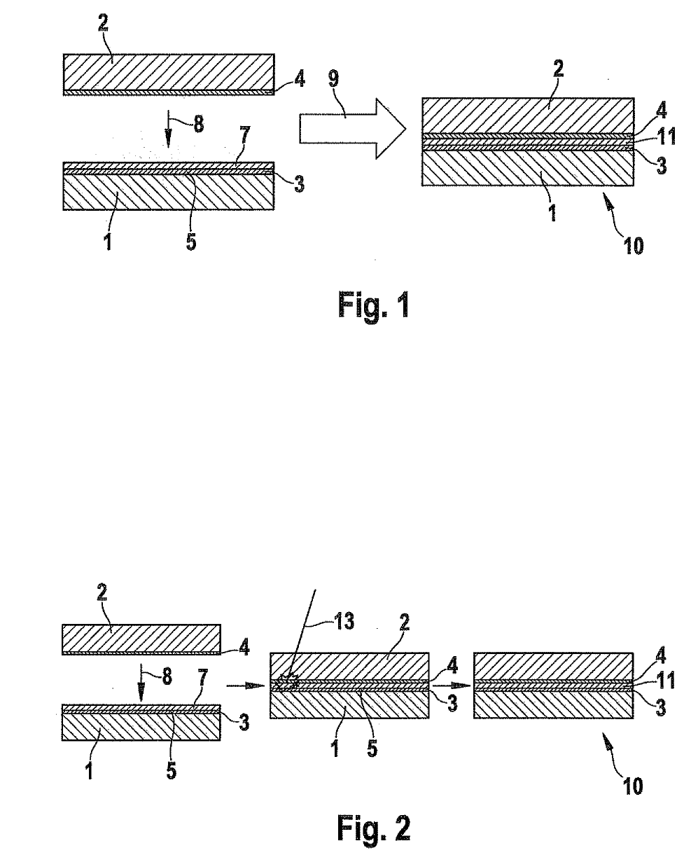

The sequence of a wafer bonding method is illustrated in FIG. 1. A section of a first wafer 1 and a second wafer 2 situated above it, which are located in a vacuum atmosphere, are shown. The wafers used may be made of silicon and/or silicon oxide and/or gallium arsenide and/or of other known wafer materials, for example.

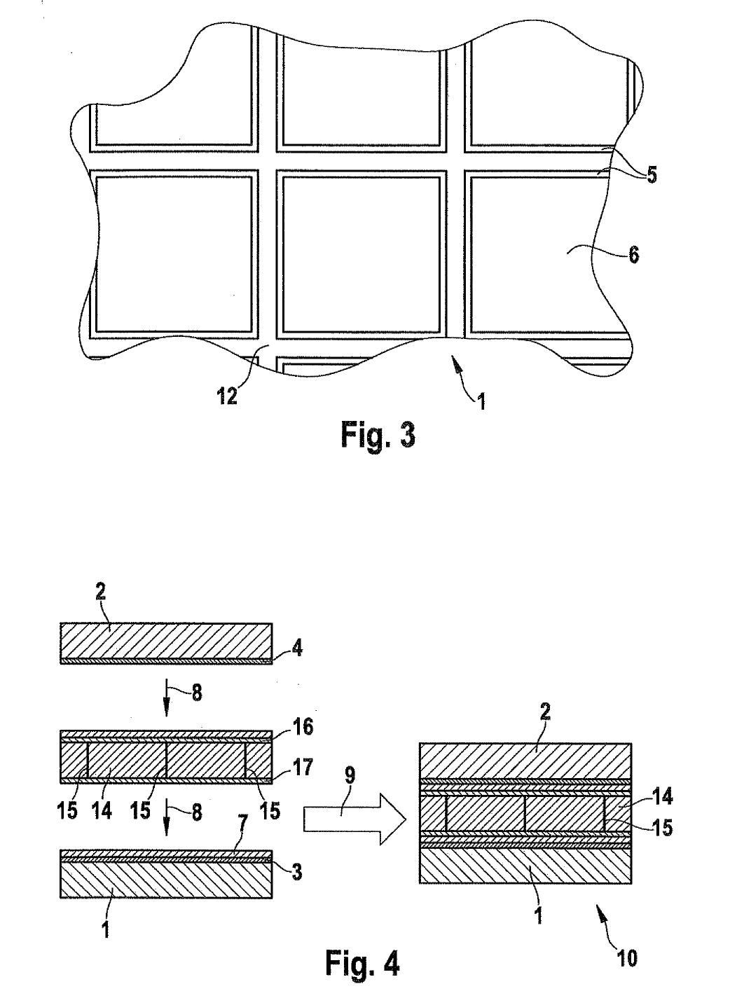

One may see that both wafers 1, 2 are provided with one metallic coating 3, 4, respectively, for example, of nickel/gold, chrome/gold, or chrome/silver. Metallic coatings 3, 4 are deposited in the form of bonding frames 5, as may be seen from FIG. 3. In the exemplary embodiment shown, the bonding frames have a quadratic ring contour, bonding frames 5 surrounding an electronic circuit 6, which is merely indicated schematically in FIG. 3, in first wafer 1, which is disposed on the bottom. FIG. 3 furthermore shows that a plurality of identical circuits 6 is disposed on first wafer 1, each one having one of these surrounding bonding frames 5. The bonding frames of second wafer 2, which are not shown, have a form that is congruent to the form of bonding frames 5 on first wafer 1.

As may be seen from FIG. 1, sinterable bonding material was deposited, for example, in a printing method, on the metallic coating (bonding frame 5) of first wafer 1.

As indicated by the arrow labeled with reference numeral 8, after bonding material 7 is deposited, after previous relative alignment, the two wafers 1, 2 are joined, i.e., brought toward each other and heated in a sinter oven. The two wafers 1, 2 are possibly pressed toward each other additionally by compression arrangement that are not illustrated. The sinter temperature is approximately 200° C. in the exemplary embodiment shown. The sinter oven process is symbolized by the arrow labeled with reference numeral 9. After a cooling phase, wafer composite 10 illustrated in the right half of the drawing according to FIG. 1 results, which is made up of first and second wafer 1, 2, two metallic coatings 3, 4, and sinter layer 11, of sintered bonding material, situated in between.

After the cooling off, individual chips may be cut out of wafer composite 10, for example, by laser cutting or conventional sawing, the cutting lines may run along regions (see FIG. 3) between adjacent bonding frames 5.

An alternative wafer bonding method may be gathered from FIG. 2. To avoid repetition, only the differences with regard to the wafer bonding methods shown in FIG. 1 and previously described are explained. With regard to the commonalities, reference is made to the previous figure description.

After first and second wafer 1, 2 having surrounded bonding material 5 are brought into contact, as labeled by arrow 8, entire wafers 1, 2 are not heated, but rather merely bonding material 7, locally. Laser radiation 13 is used for this purpose, which penetrates second wafer 2, which is transparent for laser radiation, in the illustrated exemplary embodiment. The contour of bonding frame 5 is traced with the aid of a laser scanner that is not shown. A multitude of laser scanners may also be used to bond two wafers 1, 2. It is also conceivable to direct the laser radiation through a suitable optical system homogenously at bonding material 7, that is, to produce ring-quadratic laser focus forms, for example. Wafer composite 10 illustrated in the right drawing half results from the method carried out in a vacuum atmosphere. In the method described, bonding frame 5 may be designed to be significantly thinner than in the known methods. If it is not necessary for the electric circuit to be disposed in a vacuum atmosphere, it is also conceivable to carry out the described bonding method in a normal atmosphere, in particular in a clean room.

A method that is modified to produce wafer stacks is shown in FIG. 4. In the exemplary embodiment shown, a third wafer 14 is disposed between first wafer 1 and second wafer 2, first wafer 1 and third wafer 14 being provided with a non-illustrated electronic circuit in the exemplary embodiment illustrated, and the two circuits being connected to each other in an electrically conductive manner via feedthroughs 15.

With regard to the procedure, there are different options. For example, it is conceivable to initially connect to each other first wafer 1 and third wafer 14 in a manner analogous to the method according to FIG. 1 or 2, and after that to bond second wafer 2 with the other already bonded wafers 1, 14. However, the specific embodiment shown in FIG. 4 may be used, in which all wafers 1, 2, 14 are bonded at the same time. To this end, all wafers 1, 2, 14 are provided with metallic coatings 3, 4, 16, 17 in the form of a bonding frame. On the respective upper side of first wafer 1 and of third wafer 14, bonding material 7 is deposited on metallic coatings 3, 16, whereupon all wafers are brought into contact with each other after previous mutual alignment.

After that, the sinter process labeled with reference numeral 9 takes place, if necessary additionally using compression force, it being alternatively possible to execute this sinter process in the sinter oven or in a manner supported by laser radiation. The result is the wafer composite (wafer stack) shown on the right in FIG. 4, including three wafers 1, 2, 14, the two lower wafers 1, 14 being connected to each other in an electrically conductive manner via feedthroughs 15. The topmost, second wafer 2 is merely a cap wafer, which may possibly be provided with connecting points on the outside, which are plated through to the circuit on third wafer 14 and/or the lower, first wafer 1 (not shown). Wafer stacks having a multitude of wafers may be produced using the method described. After the three wafers 1, 2, 14 have been bonded, individual chip stacks having three wafer levels may be cut out, which may be through a laser-supported cutting process.

1-15. (canceled)

16. A method for joining a first wafer to at least a second wafer, the method comprising:
depositing a sinterable bonding material on at least one of the wafers;
joining the first wafer to the at least a second wafer; and
sintering the bonding material through heating.

17. The method of claim 16, wherein the wafers are pressed against each other by one of (i) using a compression force with the aid of compression arrangement, and (ii) the compression force is produced without the compression arrangement, exclusively by a weight of at least one of the at least a second wafer, additional wafers, and additional bonding material.

18. The method of claim 16, wherein the bonding material is heated together with the wafers, in a sinter oven, to a sinter temperature below 350° C.

19. The method of claim 16, wherein the bonding material is heated locally, via laser radiation, via at least one laser scanner.

20. The method of claim 16, wherein at least one of the following is satisfied: (i) the bonding material is deposited, (ii) the wafers are brought into contact, and (iii) the sintering occurs in a vacuum.

21. The method of claim 16, wherein the wafers are metallized, at least in the subsequent contact region for the bonding material, in the form of bonding frames, before the bonding material is deposited.

22. The method of claim 16, wherein the bonding material is deposited on a bonding frame around a circuit configured on at least one of the wafers.

23. The method of claim 16, wherein the bonding material includes silver particles, preferably having a d₅₀ value that is less than 300 nm.

24. The method of claim 16, wherein at least one additive, in particular, an organic material, is mixed in with the silver particles.

25. The method of claim 16, wherein the bonding material is at least one of a paste-like bonding material and a powdery bonding material.

26. The method of claim 16, wherein the bonding material is deposited by one of stencil printing, silk-screen printing, spraying, and dispensing.

27. The method of claim 16, wherein more than two wafers are bonded to each other by sintering into a wafer stack.

28. The method of claim 16, wherein the joined wafers are divided, in particular, cut by laser beam or sawed, into individual capped chips, in particular, micromechanical sensor chips or chip stacks.

29. A wafer composite, comprising:
a first wafer;
at least a second wafer, wherein at least two of the wafers are joined together, and wherein the wafers are fixed to each other via a sintered bonding material disposed between the wafers;
wherein the first wafer is joined to the at least a second wafer, by depositing the sinterable bonding material on at least one of the wafers, joining the first wafer to the at least a second wafer, and sintering the bonding material through heating.

30. A sensor chip, including at least two wafer material levels, comprising:
a first wafer material level;
at least a second wafer material level, wherein at least two of the wafer material levels are joined together, and wherein the wafer material levels are fixed to each other via a sintered bonding material disposed between the wafer material levels;
wherein the first wafer material level is joined to the at least a second wafer material level, by depositing the sinterable bonding material on at least one of the wafer material levels, joining the first wafer material level to the at least a second wafer material level, and sintering the bonding material through heating.

31. The method of claim 16, wherein the bonding material is heated together with the wafers, in a sinter oven, to a sinter temperature below 300° C.

32. The method of claim 16, wherein the bonding material is heated together with the wafers, in a sinter oven, to a sinter temperature below 250° C.

33. The method of claim 16, wherein the bonding material is heated locally, via laser radiation, via at least one laser scanner, to a sinter temperature below 250° C.

34. The method of claim 16, wherein the bonding material includes silver particles, having a d₅₀ value that is less than 300 nm, in particular having a maximum particle size of less than 250 nm.

35. The method of claim 16, wherein the bonding material includes silver particles, having a d₅₀ value that is less than 300 nm, in particular having a maximum particle size of less than 200 nm.

36. The method of claim 16, wherein the bonding material includes silver particles, having a d₅₀ value that is less than 300 nm, in particular having a maximum particle size of less than 100 nm.

37. The method of claim 16, wherein the bonding material includes silver particles, having a d₅₀ value that is less than 300 nm, in particular having a maximum particle size of less than 50 nm.
